(19) United States
(12) Patent Application Publication
(10) Pub. No.: US 2015/0004334 A1
(43) Pub. Date: Jan. 1, 2015

(54) FOLDABLE TRANSPARENT COMPOSITE COVER WINDOW, MANUFACTURING METHOD OF THE SAME, AND FOLDABLE DISPLAY DEVICE CONTAINING THE SAME

(71) Applicant: Korea Advanced Institute of Science and Technology, Daejeon (KR)

(72) Inventors: Byeong-Soo BAE, Daejeon (KR); Gwang-Mun CHOI, Daejeon (KR); Ji-Hoon KO, Daejeon (KR)

(21) Appl. No.: 14/316,964

(22) Filed: Jun. 27, 2014

(30) Foreign Application Priority Data
Jun. 28, 2013 (KR) 10-2013-0075601

(51) Int. Cl. H05K 5/03; B32B 37/18

(52) U.S. Cl. CPC H05K 5/03; B32B 37/182; B32B 2307/412; B32B 2307/50
USPC 428/12; 156/298

(57) ABSTRACT

A foldable transparent composite cover window, a manufacturing method therefore, and a display device including the foldable transparent composite cover window are provided.

### CROSS-REFERENCE TO RELATED APPLICATION

This application claims the benefit of Korean Patent Application No. 10-2013-0075601 filed on Jun. 28, 2013, the disclosures of which are incorporated herein by reference.

### FIELD OF THE INVENTION

The present disclosure relates to a foldable transparent composite cover window, a manufacturing method therefore, and a display device including the foldable transparent composite cover window.

### BACKGROUND OF THE INVENTION

With the development of IT technologies in the IT industry, information terminals have had a tendency to be scaled-down and more light-weighted in order to improve portability thereof. However, as the amount of information transmitted through the information terminals increases, it is required to enhance the size of the information terminals rather than scaling them down. In order to meet these conflicting requirements, using a foldable display having high portability as well as a large-sized screen may be a solution. Actually, the foldable display has currently wide applications in various display fields such as smart phones, tablet PCs, PMPs (Portable Multimedia Players), navigations, electronic books, monitors, etc.

For these various displays, a cover window (protection window) touchable by a user and capable of protecting the inside of the display needs to be provided at the outermost position of each display. For the purpose, glass or hard plastic which is transparent and has high hardness has been used as the cover window. Since, however, the glass or hard plastic is easily breakable, it is practically difficult to apply them to the foldable display. Thus, a foldable part may be implemented by a soft material layer, and glass or hard plastic may be connected thereto.

Korean Patent No. 10-2012-0089077 is directed to a foldable display device including an organic light emitting device and discloses a method in which a protection window for protecting a screen is made of a hard material such as glass, and a foldable part of the display is made of a soft material. That is, in this method, two protection windows made of glass are simply connected by a soft material such as a silicon resin. Further, abutment side surfaces between the two protection windows and the soft material are inclined, and a gap between the two inclined surfaces is enlarged upward, thus minimizing discontinuity of a screen of the display that might be caused by a difference in refractive index between the protection windows and the soft material. This method, however, does not seek to solve the fundamental problem but just attempts to minimize the problem by designing the optical structure of the display. Thus, depending on the viewing angle of a user, the discontinuity of the display screen would be rather increased. Further, when folding the display actually, the connected parts may be detached. Moreover, in this method, since the two windows are directly attached on a panel of the display, manufacture of, for example, a touch screen panel circuit on the cover window may become difficult.

In order to solve these problems, the present disclosure provides a foldable transparent composite cover window including both a cover window and a plastic as a soft material. Development of such a foldable cover window is expected to be a core technology for commercialization of the foldable display.

### BRIEF SUMMARY OF THE INVENTION

In view of the foregoing problems, an illustrative embodiment of the present disclosure provides a foldable transparent composite cover window, a manufacturing method for the foldable transparent composite cover window and a display device including the foldable transparent composite cover window.

However, the problems sought to be solved by the present disclosure are not limited to the above description and other problems can be clearly understood by those skilled in the art from the following description.

In accordance with a first aspect of the present disclosure, there is provided a foldable transparent composite cover window, comprising: a transparent flexible plastic substrate; and two or more cover panels arranged at the transparent flexible plastic substrate while spaced apart from each other at a certain distance.

In accordance with a second aspect of the present disclosure, there is provided a manufacturing method for a foldable transparent composite cover window, the method comprising: arranging two or more cover panels at a transparent resin, which is to be used as a transparent flexible plastic substrate, so as to be spaced apart from each other at a certain distance; and pressing and curing the transparent resin at which the two or more cover panels are arranged.

In accordance with a third aspect of the present disclosure, there is provided a foldable display device comprising a foldable transparent composite cover window in accordance with the first aspect of the present disclosure.

In accordance with the illustrative embodiment, it is possible to manufacture the foldable transparent composite cover window. In this foldable cover window in accordance, since the difference in refractive index between the cover panels such as glass and the plastic substrate is minimized or ultimately equal to zero, light reflection or scattering at the interface between the two materials can be suppressed. Thus, while maintaining the total light transmittance high, the sense of discontinuity of the screen can be minimized. With this advantage, the foldable transparent composite cover window of the present disclosure may be applied to a foldable display device. By applying this foldable transparent composite cover window to the display device, an information terminal having both a large screen and a high portability may be achieved.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1a provides a cross sectional view of a foldable transparent composite cover window in which cover panels such as glass are positioned in a plastic substrate at a certain depth from a top surface of the plastic substrate, and FIG. 1b presents a cross sectional view of a foldable transparent composite cover window in which cover panels such as glass are positioned in a plastic substrate at a depth of the thickness of the cover panels from a top surface of the plastic substrate so as to be exposed to the top surface of the plastic substrate.

### DETAILED DESCRIPTION OF THE INVENTION

Hereinafter, illustrative embodiments and examples of the present disclosure will be described in detail so that inventive concept may be readily implemented by those skilled in the art. However, it is to be noted that the present disclosure is not limited to the illustrative embodiments and examples but can be realized in various other ways. In drawings, parts not directly relevant to the description are omitted to enhance the clarity of the drawings, and like reference numerals denote like parts through the whole of the present disclosure.

Through the whole of the present disclosure, the terms “connected to” or “coupled to” are used to designate a connection or coupling of one element to another element and include both a case where an element is “directly connected or coupled to” another element and a case where an element is “electronically connected or coupled to” another element via still another element.

Through the whole of the present disclosure, the term “on” that is used to designate a position of one element with respect to another element includes both a case that the one element is adjacent to the another element and a case that any other element exists between these two elements.

Through the whole of the present disclosure, the term “comprises or includes” and/or “comprising or including” used in the document means that one or more other components, steps, operation and/or existence or addition of elements are not excluded in addition to the described components, steps, operation and/or elements unless context dictates otherwise.

Through the whole of the present disclosure, the term “about or approximately” or “substantially” are intended to have meanings close to numerical values or ranges specified with an allowable error and intended to prevent accurate or absolute numerical values disclosed for understanding of the present disclosure from being illegally or unfairly used by any unconscionable third party.

Through the whole of the present disclosure, the term “step of” does not mean “step for”.

Through the whole of the present disclosure, the term “combinations of” included in Markush type description means mixture or combinations of one or more components, steps, operations and/or elements selected from the group consisting of components, steps, operation and/or elements described in Markush type and thereby means that the disclosure includes one or more components, steps, operations and/or elements selected from the Markush group.

Through the whole of the present disclosure, the term “A and/or B” means “A or B” or “A and B.”

Below, illustrative embodiments and examples of the present disclosure will be described in detail. However, it should be noted that the illustrative embodiments and examples are nothing more than examples and the present disclosure may not be limited thereto.

In accordance with a first aspect of the present disclosure, there is provided a foldable transparent composite cover window including a transparent flexible plastic substrate; and two or more cover panels arranged in the transparent flexible plastic substrate while spaced apart from each other at a certain gap.

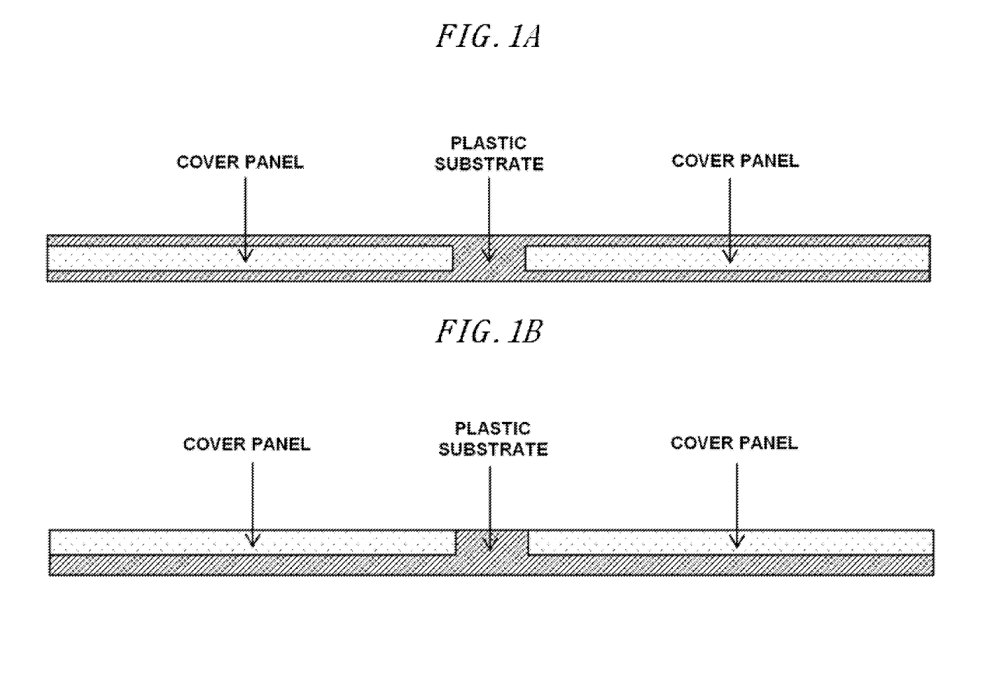

FIG. 1a is a cross sectional view of a foldable transparent composite cover window in which cover panels such as glass are positioned in a plastic substrate at a certain depth from a top surface thereof, and FIG. 1b is a cross sectional view of a foldable transparent composite cover window in which cover panels such as glass are positioned in a plastic substrate at a depth of the thickness of the cover panels from a top surface of the plastic substrate so as to be exposed to the top surface of the plastic substrate.

In one example embodiment of the present disclosure, the two or more cover panels may be provided in the plastic substrate at the certain depth from the top surface thereof or on the top portion of the plastic substrate, but may not be limited thereto. As shown in FIGS. 1a and 1b, the foldable transparent composite cover windows in accordance with the present disclosure may include the one (see FIG. 1a) in which the two or more cover panels are arranged in the plastic substrate while spaced from each other at a certain distance and the one (see FIG. 1b) in which the two or more cover panels are arranged in the top surface portion of the plastic substrate while spaced apart from each other at a certain distance.

In one example embodiment of the present disclosure, the transparent composite cover windows having the structure as depicted in FIGS. 1a and 1b may be manufactured through the process of: inserting the two or more cover panels to the inside of a transparent resin (which is a soft material) or into a top surface portion thereof such that the two cover panels are arranged spaced apart from each other at a certain distance; and then pressing and curing the transparent resin, but may not be limited thereto. Here, the transparent resin may be formed into a transparent flexible plastic substrate through a pressing process and a curing process, but may not be limited thereto.

In one example embodiment of the present disclosure, the curing process may include, but may not be limited thereto, photo-curing or heat-curing.

In one example embodiment of the present disclosure, the two or more cover panels may include a member selected from the group consisting of glass, tempered glass, polyethyleneterephthalate (PET), polycarbonate (PC), polymethyl methacrylate (PMMA), polyethylene naphthalate (PEN), polyethersulfone (PES), polyimide (PI), a cyclic olefin copolymer, and combinations thereof, but may not be limited thereto. By way of example, a difference in refractive index between the two or more cover panels and the transparent flexible plastic substrate may be about 0.05 or less, about 0.04 or less, about 0.03 or less, about 0.02 or less, or about 0.01 or less, but may not be limited thereto.

In one example embodiment of the present disclosure, by controlling the refractive index difference between the transparent flexible plastic substrate and the two or more cover panels included in the transparent composite cover window to about 0.05 or less, a difference in optical characteristics of the cover panel such as glass and the plastic substrate may be minimized, thus making a user not to feel the discontinuity of the display from an interface between the cover panel and the plastic substrate. The difference in the optical characteristics between the cover panel such as glass and the plastic substrate may reduce the overall light transmittance or make the user to feel the discontinuity of a screen of the display at a folded part.

In one example embodiment of the present disclosure, the transparent composite cover window may additionally have a plastic film on a bottom surface thereof, but may not be limited thereto. By way of example, if the transparent composite cover window is formed on the plastic film, the easiness of its manufacture may be further improved. Here, the plastic film may be flexible.

In one example embodiment of the present disclosure, the plastic film may include, a member selected from the group consisting of a styrene resin, a styrene acrylonitrile resin, a polypropylene resin, a polyethylene resin, an acrylic resin, a polyacetal resin, a polycarbonate resin, a cyclo olefin resin, a polyamide resin, a polyvinyl chloride resin, a polyester resin, a polyurethane resin, a norbornene resin, an acrylonitrile butadiene styrene resin, an epoxy resin, an ether sulfone resin, and combinations thereof, as a major component, but may not be limited thereto.

In one example embodiment of the present disclosure, the plastic film may be provided on a film including a touch circuit and a display circuit, when applied to a display device, but may not be limited thereto.

In accordance with a second aspect of the present disclosure, there is provided a manufacturing method for the foldable transparent composite cover window in accordance with the first aspect of the present disclosure. The manufacturing method includes arranging two or more cover panels on a transparent resin, which is to be used as a transparent flexible plastic substrate, so as to be spaced apart from each other at a certain distance; and pressing and curing the transparent resin on which the two or more cover panels are arranged.

In one example embodiment of the present disclosure, arranging the two or more cover panels at the certain distance therebetween may include arranging them such that the two or more cover panels spaced apart from each other at the certain distance are located in the transparent resin at a certain depth from the top surface of the transparent resin, or located on a top portion of the transparent resin but may not be limited thereto.

In one example embodiment of the present disclosure, the transparent composite cover windows having the structure as depicted in FIGS. 1a and 1b may be manufactured through the process of: inserting the two or more cover panels to the inside of a transparent resin (which is a soft material and to be used as a transparent flexible plastic substrate), or on a top portion of the transparent resin such that the two cover panels are arranged spaced apart from each other at the certain distance; and then pressing and curing the transparent resin, but may not be limited thereto. Here, the transparent resin may be formed into a transparent plastic substrate through a pressing process and a curing process, but may not be limited thereto.

In one example embodiment of the present disclosure, the curing process may include, photo-curing or heat-curing, but may not be limited thereto.

In one example embodiment of the present disclosure, the two or more cover panels may include, a member selected from the group consisting of glass, tempered glass, polyethyleneterephthalate (PET), polycarbonate (PC), polymethyl methacrylate (PMMA), polyethylene naphthalate (PEN), polyethersulfone (PES), polyimide (PI), cyclic olefin copolymer (COC), and combinations thereof, but may not be limited thereto.

In one example embodiment of the present disclosure, the transparent resin may include a member selected from the group consisting of a siloxane resin, a silicon resin, an acrylic resin, an epoxy resin, a styrene resin, a styrene acrylonitrile resin, a polycarbonate resin, a polyester resin, a polyurethane resin, an acrylonitrile butadiene styrene resin, and combinations thereof, but may not be limited thereto.

In one example embodiment of the present disclosure, the transparent resin forming the composite body by being pressed along with the two or more cover panels may have flexibility to the extent that no crack would be generated even when it is bent several to several thousands of times repeatedly after cured into a transparent plastic substrate.

In one example embodiment of the present disclosure, the transparent composite cover window may have a plastic film on a bottom surface thereof, but may not be limited thereto. By way of example, the transparent composite cover window may be manufactured by first coating the transparent resin on the flexible plastic film; inserting two or more cover panels to the inside of or on a top portion of the transparent resin such that the two cover panels are spaced apart from each other at a certain distance; and then pressing and curing the transparent resin.

In case of forming the transparent composite cover window on the plastic film, the easiness of its manufacture may be further improved. Here, the plastic film may be flexible, but may not be limited thereto.

In one example embodiment of the present disclosure, the plastic film may include a member selected from the group consisting of a styrene resin, a styrene acrylonitrile resin, a polypropylene resin, a polyethylene resin, an acrylic resin, a polyacetal resin, a polycarbonate resin, a cyclo olefin resin, a polyamide resin, a polyvinyl chloride resin, a polyester resin, a polyurethane resin, a norbornene resin, an acrylonitrile butadiene styrene resin, an epoxy resin, an ether sulfone resin, and combinations thereof, as a major component, but may not be limited thereto.

In one example embodiment of the present disclosure, in the manufacturing method of the transparent composite cover window, in order to improve adhesiveness between the transparent resin and the cover panels, a surface treatment typically performed in the relevant art, such as a UV-zone treatment, a flame treatment, a degassing treatment, or a plasma treatment, may be additionally performed on the cover panels before the two or more panels are arranged apart from each other at the certain distance.

In accordance with a third aspect of the present disclosure, there is provided a foldable display device including the foldable transparent composite cover window in accordance with the first aspect of the present disclosure.

For the foldable display device in accordance with the third aspect of the present disclosure, parts similar or identical to those described in the first aspect of the present disclosure will be omitted. The description provided for the first aspect of the present disclosure will also be applied to the third aspect of the present disclosure, though omitted.

Below, examples of the illustrative embodiment will be described. However, the following examples are intended to facilitate understanding of the present disclosure and therefore are not intended to limit its scope.

### EXAMPLES

Refractive indexes of materials described in the following examples were measured at a wavelength of about 589 nm by using Abbe Refractometer.

### Example 1

### Manufacture 1 of Foldable Transparent Composite Cover Window

As a soft material, a siloxane resin (produced by Solip Tech Co., Ltd.) having a refractive index of 1.51 was coated in a thickness of 150 μm. Then, two thin film glasses, each of which has a thickness of 100 μm and a refractive index of 1.51, were placed at both opposite sides on the siloxane resin so as to be spaced apart from each other at a distance of about 2 cm and pressed. Then, the siloxane resin was photo-cured, whereby a foldable transparent composite cover windows having a cross section as depicted in FIGS. 1a and 1b were obtained.

### Example 2

### Manufacture 2 of Foldable Transparent Composite Cover Window

As a soft material, methyl methacrylate (MMA) (produced by Gelest) having a refractive index of 1.49 was coated in a thickness of 150 μm. Then, two thin film glasses, each of which has a thickness of 100 μm and a refractive index of 1.51, were placed at both opposite sides on the MMA so as to be spaced apart from each other at a distance of about 2 cm and pressed. Then, the MMA was heat-cured by using 2,2′-azobis(isobutyronitrile) (AIBN) (produced by Aldrich) as an initiator to thereby produce polymethyl methacrylate (PMMA). Through this process, a foldable transparent composite cover windows having a cross section as depicted in FIGS. 1a and 1b were obtained.

### Comparative Example 1

### Manufacture of Transparent Composite Cover Window Having a Large Difference in Refractive Index

As a soft material, Sylgard 184 (produced by Dow Corning) having a refractive index of 1.43 was coated in a thickness of 150 μm, and two thin film glasses, each of which has a thickness of 100 μm and a refractive index of 1.51, were placed at both opposite sides on the coating of Sylgard 184 so as to be spaced apart from each other at a distance of about 2 cm and pressed. Then, the Sylgard 184 was heat-cured, whereby a foldable transparent composite cover windows having a cross section as depicted in FIGS. 1a and 1b were obtained.

### EXPERIMENTAL EXAMPLES

### Performance Test

### 1. Bending Test

In order to evaluate the flexibility of the foldable transparent composite cover windows obtained in the above examples, bending test with a radius of curvature of 5 mm was performed repeatedly 1000 times. Depending on whether cracks are generated or not, a success or a failure in passing the test was confirmed. The results are shown in Table 1 below where O indicates that no crack was generated and X indicates that a crack was generated.

2. Total transmittance and Haze

In order to measure the total transmittance and the haze of the foldable transparent composite cover windows acquired in the above examples, a Haze meter according to JIS K7105 was used, and the measurement results are provided in Table 1 below.

TABLE 1

| | | | Total | |
|---|---|---|---|---|
| | | Bending | Transmittance | |
| | n_{glass}-n_{plastic} | Test | (%) | Haze |
| Example 1 | 0 | ◯ | 90.2 | 0.9 |
| Example 2 | 0.02 | ◯ | 89.1 | 1.5 |
| Comparative | 0.08 | ◯ | 85.8 | 4.2 |
| Example 1 | | | | |

As can be seen from Table 1, in each of the foldable transparent composite cover windows in Examples 1 and 2, since the difference in refractive index between glass and plastic as a soft material was reduced to below 0.05, i.e., set to be almost same, high total transmittance and low haze could be obtained. In contrast, in the foldable transparent composite cover window manufactured in Comparative example 1, since the difference in refractive index between glass and plastic was over 0.05, low total transmittance and high haze were observed.

This result indicates that as the difference in optical characteristics of the cover panel such as glass and the plastic substrate increases, total transmittance would be reduced and haze would be adversely affected, making a user to feel discontinuity of the display. Besides, in the bending test repeatedly performed one thousand times, it was also confirmed that the foldable transparent composite cover windows in Examples 1 and 2 maintained their flexibility without suffering crack generation.

As described above, the foldable transparent composite cover window in accordance with the example embodiment of the present disclosure has flexibility. Further, by minimizing the difference in refractive index between the cover panel such as glass and the plastic as a soft material, reflection or scattering of light at the interface between these two materials can be suppressed, thus achieving high total transmittance and low haze. Accordingly, a user's sense of discontinuity of a screen can be minimized.

The above description of the illustrative embodiments is provided for the purpose of illustration, and it would be understood by those skilled in the art that various changes and modifications may be made without changing technical conception and essential features of the illustrative embodiments. Thus, it is clear that the above-described illustrative embodiments are illustrative in all aspects and do not limit the present disclosure. For example, each component described to be of a single type can be implemented in a distributed manner. Likewise, components described to be distributed can be implemented in a combined manner.

The scope of the inventive concept is defined by the following claims and their equivalents rather than by the detailed description of the illustrative embodiments. It shall be understood that all modifications and embodiments conceived from the meaning and scope of the claims and their equivalents are included in the scope of the inventive concept.

What is claimed is:

1. A foldable transparent composite cover window, comprising:
a transparent flexible plastic substrate; and
two or more cover panels arranged in the transparent flexible plastic substrate while spaced apart from each other.

2. The foldable transparent composite cover window of claim 1,
wherein the two or more cover panels include a member selected from the group consisting of glass, tempered glass, polyethyleneterephthalate, polycarbonate, polymethyl methacrylate, polyethylene naphthalate, polyethersulfone, polyimide, a cyclic olefin copolymer, and combinations thereof.

3. The foldable transparent composite cover window of claim 1,
wherein the two or more cover panels are positioned in the transparent flexible plastic substrate at a certain depth from a top surface thereof, or positioned on a top portion of the transparent plastic substrate.

4. The foldable transparent composite cover window of claim 1,
wherein the transparent flexible plastic substrate is prepared by curing a resin composition containing a member selected from the group consisting of a siloxane resin, a silicon resin, an acrylic resin, an epoxy resin, a styrene resin, a styrene acrylonitrile resin, a polycarbonate resin, a polyester resin, a polyurethane resin, an acrylonitrile butadiene styrene resin, and combinations thereof.

5. The foldable transparent composite cover window of claim 1,
wherein a difference in refractive index between the two or more cover panels and the transparent flexible plastic substrate is about 0.05 or less.

6. The foldable transparent composite cover window of claim 1, further comprising:
a plastic film provided on a bottom surface thereof.

7. The foldable transparent composite cover window of claim 6,
wherein the plastic film includes a member selected from the group consisting of a styrene resin, a styrene acrylonitrile resin, a polypropylene resin, a polyethylene resin, an acrylic resin, a polyacetal resin, a polycarbonate resin, a cyclo olefin resin, a polyamide resin, a polyvinyl chloride resin, a polyester resin, a polyurethane resin, a norbornene resin, an acrylonitrile butadiene styrene resin, an epoxy resin, an ether sulfone resin, and combinations thereof, as a major component.

8. The foldable transparent composite cover window of claim 6,
wherein, the plastic film is provided on a film including a touch circuit and a display circuit, when applied to a display device.

9. A manufacturing method for a foldable transparent composite cover window, the method comprising:
arranging two or more cover panels in a transparent resin which is to be used as a transparent flexible plastic substrate, so as to be spaced apart from each other; and
pressing and curing the transparent resin in which the two or more cover panels are arranged.

10. The manufacturing method of claim 9,
wherein the two or more cover panels include a member selected from the group consisting of glass, tempered glass, polyethyleneterephthalate, polycarbonate, polymethyl methacrylate, polyethylene naphthalate, polyethersulfone, polyimide, a cyclic olefin copolymer, and combinations thereof.

11. The manufacturing method of claim 9,
wherein the arranging the two or more cover panels so as to be spaced apart from each other includes arranging the two or more cover panels such that the two or more cover panels are provided in the transparent resin at a certain depth from a top surface thereof or provided on a top portion of the transparent resin.

12. The manufacturing method of claim 9,
wherein the transparent resin includes a member selected from the group consisting of a siloxane resin, a silicon resin, an acrylic resin, an epoxy resin, a styrene resin, a styrene acrylonitrile resin, a polycarbonate resin, a polyester resin, a polyurethane resin, an acrylonitrile butadiene styrene resin, and combinations thereof.

13. A foldable display device comprising a foldable transparent composite cover window as claimed in claim 1.
